(19) United States
(12) Patent Application Publication
(10) Pub. No.: US 2014/0319488 A1
(43) Pub. Date: Oct. 30, 2014

(54) THIN FILM FORMATION FOR DEVICE SENSITIVE TO ENVIRONMENT

(71) Applicant: Veeco ALD Inc., Fremont, CA (US)

(72) Inventor: Sang In Lee, Sunnyvale, CA (US)

(73) Assignee: Veeco ALD Inc., Fremont, CA (US)

(21) Appl. No.: 14/248,968

(22) Filed: Apr. 9, 2014

Related U.S. Application Data
(60) Provisional application No. 61/815,980, filed on Apr. 25, 2013.

(51) Int. Cl. H01L 51/52; H01L 51/56

(52) U.S. Cl. CPC H01L 51/5253; H01L 51/56
USPC 257/40; 438/46

(57) ABSTRACT

Embodiments relate to forming a barrier layer on a device before performing radical-assisted atomic layer deposition (RA-ALD) using ozone to form oxygen radicals that function as a reactant precursor for depositing a blanket deposition layer over the device. Before exposing the substrate to ozone or oxygen radicals generated from ozone or oxygen radicals with hydroxyl radicals (generated from ozone mixed with hydrogen-containing gas such as hydrogen or ammonia), the barrier layer is formed on the substrate by exposing the device formed on a substrate to radicals of nitrogen compound gas to prevent ozone, its radicals or oxygen radicals in combination with hydroxyl radicals from penetrating and damaging the device during the process of depositing the blanket deposition layer.

### CROSS-REFERENCE TO RELATED APPLICATION

This application claims priority under 35 U.S.C. §119(e) to co-pending U.S. Provisional Patent Application No. 61/815,980 filed on Apr. 25, 2013, which is incorporated by reference herein in its entirety.

### BACKGROUND

1. Field of Art

The present disclosure relates to depositing a layer of material on a structure for encapsulation or blanket deposition using radical assisted atomic layer deposition (RA-ALD) to protect the structure against environment.

2. Description of the Related Art

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor.

ALD can be a slow process that can take an extended amount of time or many repetitions before a layer of desired thickness can be obtained. Hence, to expedite the process, a vapor deposition reactor with a unit module (so-called a linear injector), as described in U.S. Patent Application Publication No. 2009/0165715 or other similar devices may be used to expedite ALD process. The unit module includes an injection unit and an exhaust unit for a source material (a source module), and an injection unit and an exhaust unit for a reactant (a reactant module).

It is advantageous to encapsulate display devices such as organic light-emitting diode (OLED) devices by a blanket deposition layer to prevent moisture or oxygen from causing damage during their use. Such blanket deposition layer may be formed using various materials including polymeric films, oxides (e.g., SiO₂ and Al₂O₃) and nitrides (e.g., SiNₓ). More than one layer of materials may be formed on the display devices to increase the effectiveness of the encapsulation. A commonly used measure of encapsulation is water vapor transmission rate (WVTR). WVTR is the steady state rate at which water vapor permeates through a film at specified conditions of temperature and relative humidity. A lower WVTR of a blanket deposition layer indicates that the blanket deposition layer is more effective in preventing penetration of moisture.

In other applications, a blanket layer of low temperature oxide material may be deposited over a patterned structure of photoresist layer by an atomic layer deposition (ALD) technique to modify the pitch between the patterns. Generally, photoresist materials are not tolerant to ozone or radicals generated from ozone at high temperature. Therefore, ozone or radicals generated from ozone was not frequently used in the process of forming spacers.

### SUMMARY

Embodiments related to deposing a barrier layer over a structure on a substrate by a barrier layer before depositing a blanket deposition layer using radicals generated from ozone. To deposit the barrier layer over the structure, source precursor is injected onto the structure and the substrate. First radicals are generated from first gas containing nitrogen compound. The generated first radicals are then injected onto the structure and the substrate to form the barrier layer by an atomic layer deposition (ALD) process. Second radicals are generated from second gas containing more ozone than the first gas. The second radicals are injected onto the structure and the substrate to form a blanket deposition layer over the barrier layer by an ALD process.

In some embodiments, the processes of depositing the barrier layer are repeated for a predetermined number of times. Further, the processes of depositing the blanket deposition layer are also repeated for a predetermined number of times.

In some embodiments, the source precursor is also injected onto the structure and the substrate after injecting the first radicals and before injecting the second radicals.

In some embodiments, the structure comprises organic light-emitting diode (OLED).

In some embodiments, the nitrogen compound comprises nitrous oxide.

In some embodiments, the nitrogen compound comprises at least one of N₂O and NH₃.

In some embodiments, the source precursor includes at least one of trimethylaluminum (TMA), tris[dimethylamino]Silane (3DMAS), hexamethyldisilazane (HMDS), Di[isopropylamino]silane (DiPAS), and Tetrakis[dimethylamino]titanium (TDMAT).

In some embodiments, the barrier layer comprises at least one of Al₂O₃, AlN, and SiO₂.

In some embodiments, the barrier layer has a thickness of 1 to 100 Å.

In some embodiments, the blanket deposition layer includes at least one of Al₂O₃SiO₂, ZrO₂, TiO₂, and HfO₂.

In some embodiments, the barrier layer has a thickness of 1 to 100 Å.

In some embodiments, the blanket deposition layer has a thickness of 100 to 1000 Å.

In some embodiments, the blanket deposition layer has a thickness of 100 to 500 Å.

In some embodiments, the first and second radicals are generated by remote-plasma generation.

In some embodiments, the structure comprises a photoresist array or elongated photoresist mandrels.

In some embodiments, a conformal blanket deposition layer is form on the photoresist mandrels to perform pitch doubling. The conformal blanket deposition layer comprises SiO₂ deposited at low temperature below 100° C.

Embodiments also relate to an organic light-emitting diode (OLED) device including a blanket deposition layer and a barrier layer to prevent damage to the device during a process of forming the blanket deposition layer. The OLED device includes a substrate, a first electrode formed on the substrate, a second electrode and an organic material sandwiched between the first electrode and the second electrode. The barrier layer is formed on the second electrode and the substrate by exposure to a first source precursor and first radicals generated from first gas containing nitrogen compound. The blanket deposition layer is formed on the barrier layer by exposure to a second source precursor and second radicals generated from second gas containing more ozone than the first gas.

In some embodiments, the first and second source precursors are the same type of gas.

### BRIEF DESCRIPTION OF DRAWINGS

FIG. 1 is a cross sectional diagram of a linear deposition device, according to one embodiment.

FIG. 2 is a perspective view of a linear deposition device, according to one embodiment.

FIG. 3 is a perspective view of a rotating deposition device, according to one embodiment.

FIG. 4A is a perspective view of an injector in a deposition device, according to one embodiment.

FIG. 4B is a cross-sectional view of the injector of FIG. 4A, according to one embodiment.

FIG. 5A is a perspective view of a radical reactor in a deposition device, according to one embodiment.

FIG. 5B is a cross-sectional view of the radical reactor of FIG. 5A, according to one embodiment.

FIG. 6 is a schematic cross-sectional view of an organic light-emitting diode (OLED), according to one embodiment.

FIG. 7A is a cross-sectional view of OLED formed with a barrier layer and a blanket deposition layer, according to one embodiment.

FIGS. 7B through 7D are cross-sectional views illustrating the process of forming spacers on a substrate, according to one embodiment.

FIG. 8 is a plan view of a rotating deposition apparatus for depositing a barrier layer and a blanket deposition layer, according to one embodiment.

FIG. 9 is a plan view of a rotating deposition apparatus for depositing a barrier layer and a blanket deposition layer, according to another embodiment.

FIG. 10 is a flowchart illustrating a process of depositing a barrier layer and a blanket deposition layer on a device, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to forming a barrier layer on a structure before performing radical-assisted atomic layer deposition (RA-ALD) using ozone to form oxygen radicals that function as a reactant precursor for depositing a blanket deposition layer over the structure. Before exposing the substrate to ozone or oxygen radicals generated from ozone or oxygen radicals with hydroxyl radicals (generated from ozone mixed with hydrogen-containing gas such as hydrogen or ammonia), the barrier layer is formed on the substrate by exposing the structure formed on a substrate to radicals of nitrogen compound gas to prevent ozone, its radicals or oxygen radicals in combination with hydroxyl radicals from penetrating and damaging the device during the process of depositing the blanket deposition layer. In this way, the highly reactive ozone molecules, oxygen radicals or oxygen radicals with hydroxyl radicals can be used to form the blanket deposition layer while preventing damages to the device formed on the substrate.

The structure described herein refers to configuration of material formed on a substrate. The structure may be a flat layer of material or patterned layer of material formed on the substrate.

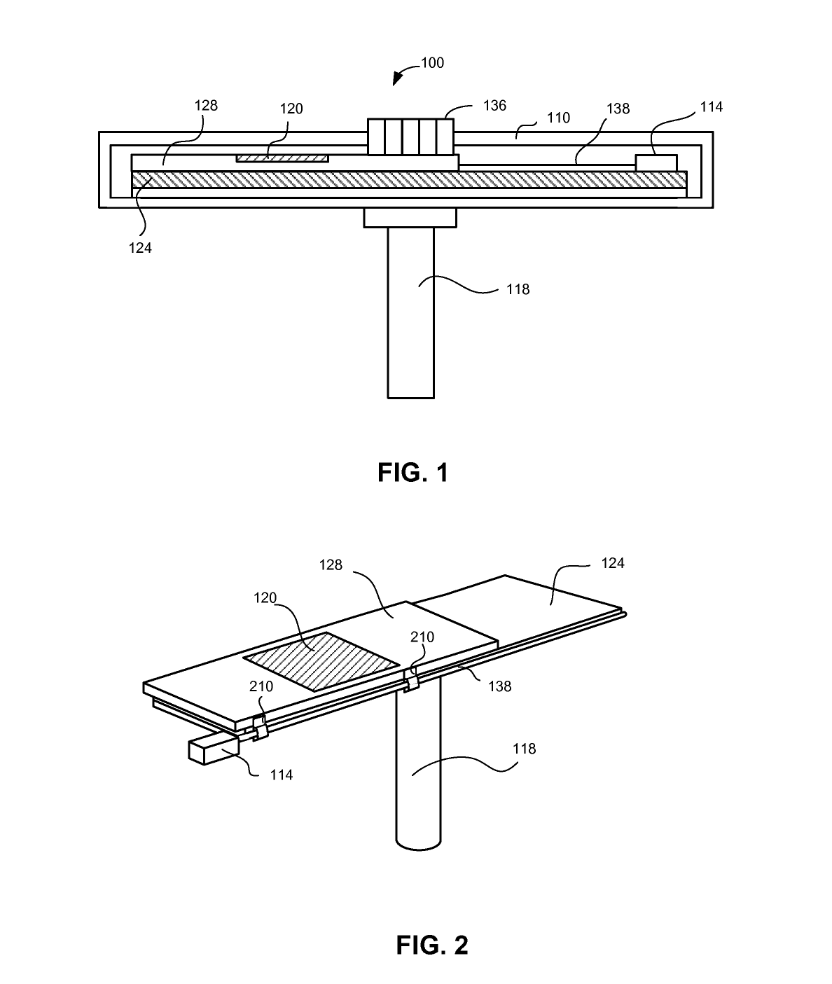

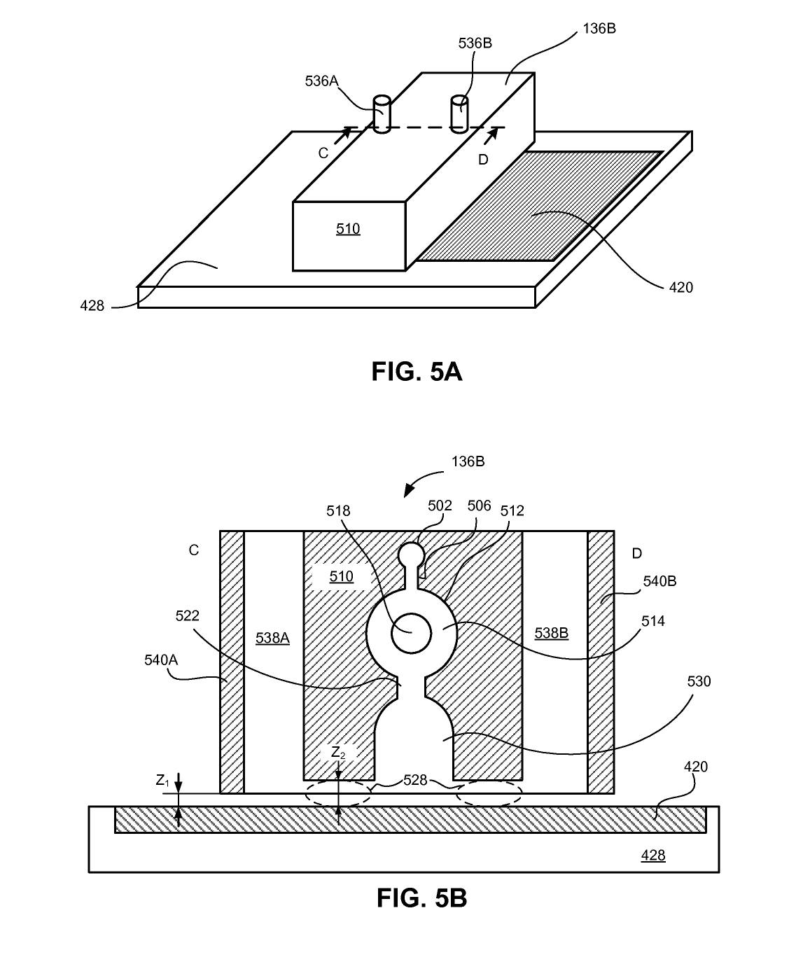

FIG. 1 is a cross sectional diagram of a linear deposition device 100, according to one embodiment. FIG. 2 is a perspective view of the linear deposition device 100 (without chamber walls to facilitate explanation), according to one embodiment. The linear deposition device 100 may include, among other components, a support pillar 118, the process chamber 110 and one or more reactors 136. The reactors 136 may include one or more of injectors and radical reactors. Each of the injectors injects source precursors, reactant precursors, purge gases or a combination of these materials onto the substrate 120. As described below in detail with reference to FIG. 5, source precursors and/or reactant precursors may be radicals of a gas mixture.

The process chamber enclosed by the walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion at the bottom, top or side of the susceptor 128). Moreover, instead of moving the susceptor 128, the susceptor 128 may remain stationary and the reactors 136 may be moved.

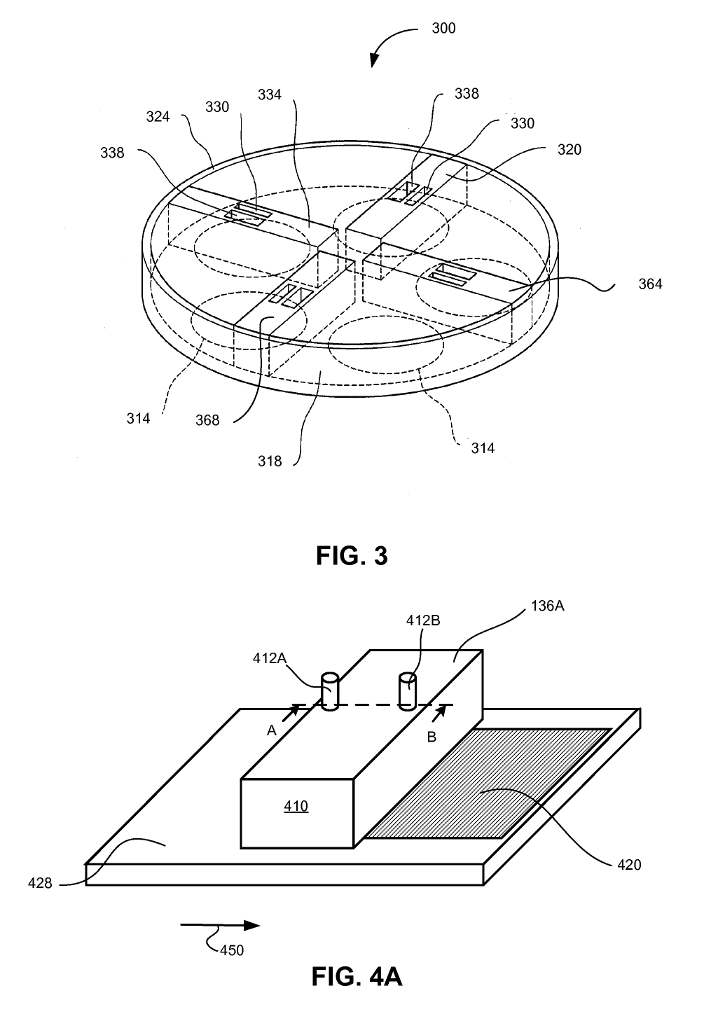

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320A, 320B, 334A, 334B, 364A, 364B, 368A, 368B, a susceptor 318, and a container 324 enclosing these components. A set of reactors (e.g., 320A and 320B) of the rotating deposition device 300 correspond to the reactors 136 of the linear deposition device 100, as described above with reference to FIG. 1. The susceptor 318 secures the substrates 314 in place. The reactors 320A, 320B, 334A, 334B, 364A, 364B, 368A, 368B are placed above the substrates 314 and the susceptor 318. Either the susceptor 318 or the reactors 320, 334, 364, 368 rotate to subject the substrates 314 to different processes.

One or more of the reactors 320A, 320B, 334A, 334B, 364A, 364A, 368B, 368B are connected to gas pipes (not shown) to provide source precursor, reactor precursor, purge gas and/or other materials. The materials provided by the gas pipes may be (i) injected onto the substrate 314 directly by the reactors 320A, 320B, 334A, 334B, 364A, 364B, 368A, 368B, (ii) after mixing in a chamber inside the reactors 320A, 320B, 334A, 334B, 364A, 364B, 368A, 368B, or (iii) after conversion into radicals by plasma generated within the reactors 320A, 320B, 334A, 334B, 364A, 364B, 368A, 368B. After the materials are injected onto the substrate 314, the redundant materials may be exhausted through outlets 330, 338. The interior of the rotating deposition device 300 may also be maintained in a vacuum state.

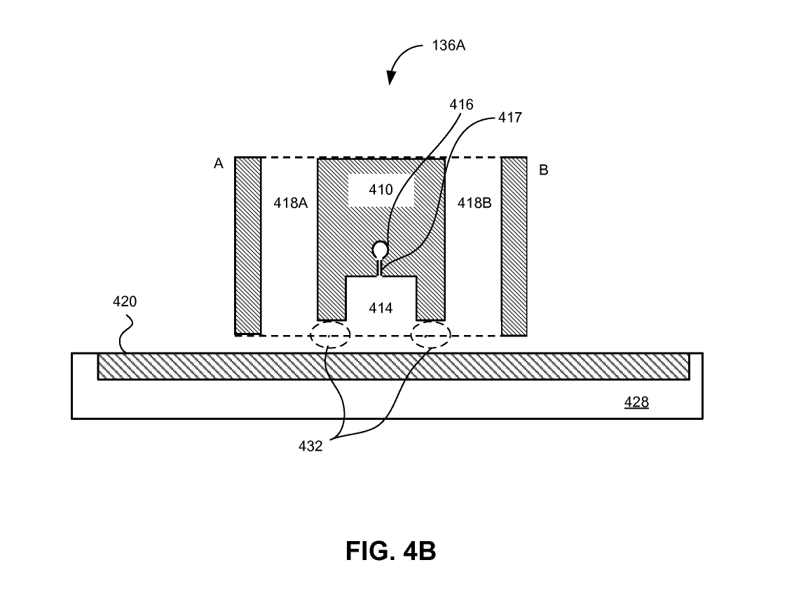

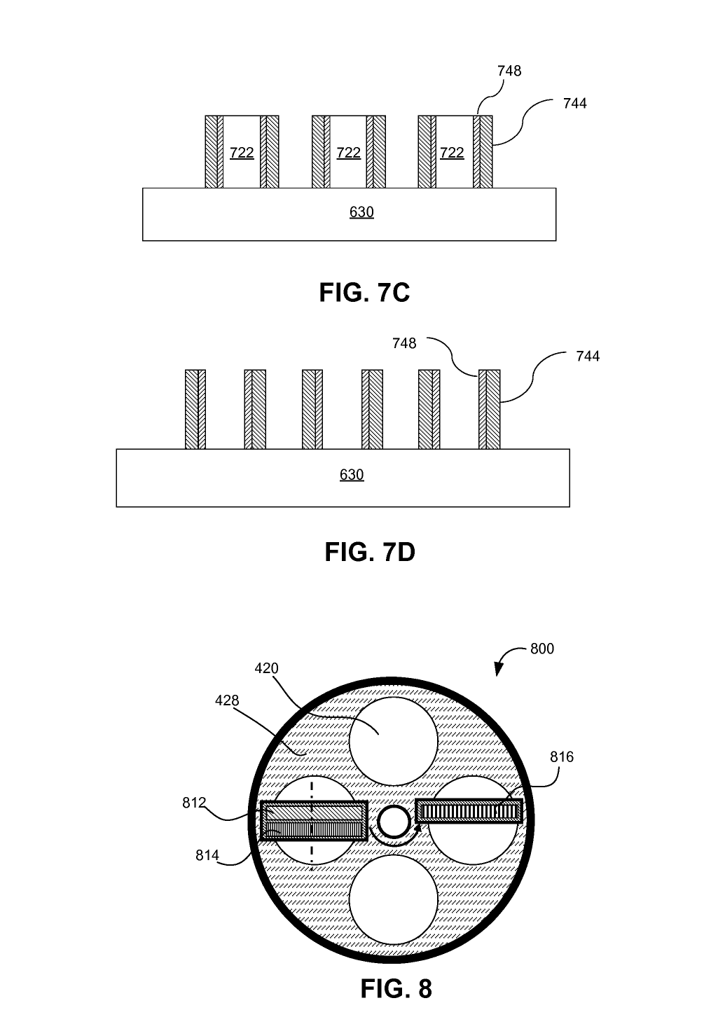

FIG. 4A is a perspective view of an injector 136A, according to one embodiment. The injector 136A injects gas onto the substrate 420 (received in a susceptor 428) to deposit material or treat the surface of the substrate 420. The injector 136A has a body 410 which is connected to receive the gas from a pipe (not shown). The gas remaining after exposure to the substrate 420 is discharged via exhaust pipes 412A, 412B. Different portions of the substrate 420 is exposed to the gas injected by the injector 136A as the susceptor 428 and the substrate 420 moves from the left to the right, as shown by arrow 450. In other embodiments, the substrate 420 may reciprocate in both directions (i.e., from the left to the right and from the right to the left) to deposit a layer of material of a desired thickness. The injector 136A may be used to inject a source precursor for depositing a barrier layer or a blanket deposition layer, as described below in detail with reference to FIGS. 7 through 9.

FIG. 4B is a cross-sectional view of the injector 136A taken along line A-B of FIG. 4A, according to one embodiment. The gas provided to the injector 136A is carried to reaction chamber 414 via a channel 416 and perforations 417 formed in the body 410. Below the reaction chamber 414, the substrate 420 comes into contact with the gas. The gas remaining after injection onto the substrate 420 is discharged from the injector 136A via constriction zones 432 and exhaust portions 418A, 418B.

FIG. 5A is a perspective view of a radical reactor 136B, according to one embodiment. The reactor 136B may be a radical reactor that generates radicals of gas or a gas mixture received from one or more sources. The radical reactor 136B may be used to generate and inject radicals functioning as a reactant precursor for depositing a barrier layer or a layer, as described below in detail with reference to FIGS. 7 through 9. The gas or gas mixtures are injected into the reactor 136B via a pipe (not shown), and are converted into radicals within the reactor 136B by applying voltage across electrodes. The radicals are injected onto the substrate 420, and remaining radicals and/or gas reverted to inactive state are discharged from the reactor 136B via exhaust pipes 538A, 538B.

FIG. 5B is a cross-sectional view of the radical reactor 136B taken along line C-D of FIG. 5A, according to one embodiment. The radical reactor 136B has a similar structure as the injector 136A except that the radical reactor further includes a plasma generator. The plasma generator includes an inner electrode 518 and an outer electrode 512 surrounding a plasma chamber 514 (the outer electrode 512 may be part of a metallic body 510). The body 510 is formed with, among others, a gas channel 502, perforations (slits or holes) 506, the plasma chamber 514, an injector slit 522, a reaction chamber 530 and exhaust portions 538A, 538B. A gas or a mixture of gases is injected via the channel 502 and perforations 506 into the plasma chamber 514.

By applying a voltage difference between the inner electrode 518 and the outer electrode 512, plasma is generated in the plasma chamber 514. As a result of the plasma, radicals of the gas or the mixture of gases are generated within the plasma chamber 514. The generated radicals are injected into the reaction chamber 414 via the injector slit 522. The region of the substrate 120 below the reaction chamber 530 comes into contact with the radicals, depositing a layer of material on the substrate 420 by an RA-ALD process. Because the radicals are generated in the plasma chamber 514 that is located away from the substrate 420, the process performed by the radical reactor 136B is referred to as a remote-plasma generation.

The distance between the plasma chamber 514 and the substrate 420 is configured so that a sufficient amount of radicals reach the substrate 420 in an active state. Radicals have a predetermined lifetime. Hence, as the radicals travel via the injector slit 522 and the reaction chamber 530 to the substrate 420, some of the radicals revert back to an inactive gaseous state. With the increase in the travel distance, the amount of radicals reverting to the inactive gaseous state increases. Hence, it is advantageous to set the distance between the plasma chamber 514 and the substrate 420 to be less than a certain length. For example, the distance between the plasma chamber 514 and the substrate 420 is set to 10 to 100 mm.

When using radicals of nitrogen, and nitrogen containing gas mixtures (e.g., N₂O and NH₃ mixture), the lifespan of the radicals such as N* or H* radicals is relatively short (often shorter than 1 msec), and most of the radicals revert back to an inactive state if the distance H is 80 mm or more. Hence, the distance H is set to be less than 80 mm when using radicals of nitrogen containing gas mixtures.

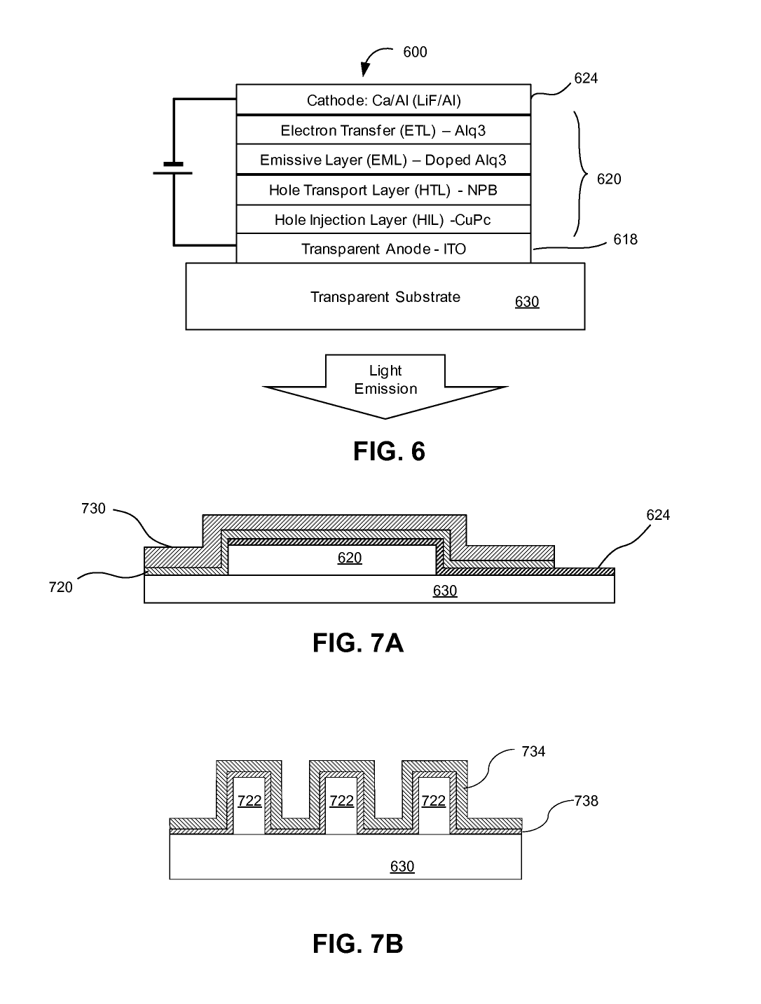

FIG. 6 is a schematic cross-sectional view of an organic light-emitting diode (OLED) device 600, according to one embodiment. The OLED device 600 may include a transparent substrate 630 (e.g., a glass), transparent anode 618, layers 620 of materials, and a cathode 624. The layers 620 may include, for example, a hole injection layer (HIL) layer, a hold transport layer (HTL) layer, an emissive layer (HML), and an electron transfer (ETL) layer. On top of the layers 620, the cathode (electrode) layer 624 is formed. When voltage difference is applied across the cathode 624 and the anode 618, light is generated and emitted from the transparent substrate 630 at the bottom. OLED device 600 is merely an example, and various embodiments described herein may be applied to other types OLED (e.g., single-layered OLED device or triple-layered top-emitting OLED device).

The layers 620 may become damaged if exposed to ozone, ozone radicals or moisture that penetrates through the cathode 624. Damage to the layers 620 may cause the OLED device 600 to become inoperable. Hence, a blanket deposition layer may be formed over the cathode 624 and/or the layers 620 to prevent penetration of oxygen or moisture after the OLED device 600 is fabricated. Although various chemical or radicals may be used to form a blanket deposition layer, the use of ozone, its radicals or its radicals in combination with hydroxyl radicals as a reactant precursor in an RA-ALD process generally results in a blanket deposition layer with superior characteristics. Materials of blanket deposition layer that may be formed by RA-ALD process using ozone or radicals generated from ozone include, for example, oxides such as SiO₂, Al₂O₃, ZrO₂, TiO₂, and HfO₂.

The high quality of oxide films generated by using ozone or its radicals is partly due to high reactivity of ozone. The high reactivity of ozone contributes to an increased amount of radicals to be generated in the radical reactors compared to oxygen. Moreover, the oxide layer formed by using O* radicals from ozone plasma tend to have lower stress with higher growth rate than those of an oxide layer formed by using O* radicals from oxygen plasma. Hence, the use of ozone to generate O* radicals is advantageous in forming a thinner and denser blanket deposition layer, especially adapted for use in flexible OLEDs.

However, the use of ozone as a source of O* radicals also accompany the risk of damaging devices formed on the substrate by ozone molecules (not activated into O* radicals) that may penetrate into the devices or decompose structures in the devices. Compounds used in forming OLED devices or photoresists are especially vulnerable to damage by ozone. Hence, ozone and its radicals have generally not been used in the process of fabricating OLED devices or oxide layers on the photoresist layer.

Embodiments enable the use of ozone, its radicals or its radicals in combination with hydroxyl radicals by forming a barrier layer on structures of devices before exposing the substrate or the structures of the devices to ozone, its radicals or hydroxyl radicals. The barrier layer may be made of the same or similar material as the blanket deposition layer, but the process for forming the barrier layer preferably uses less of ozone, its radicals or hydroxyl radicals, or uses no ozone, its radicals or hydroxyl radicals at all. Advantageously, the thickness of the barrier layer may be set to be thicker than the diffusion distance of ozone or hydroxyl radical at a given temperature for performing the deposition process so that the ozone or hydroxyl radical can be prevented from coming into contact with the layers 620.

FIG. 7A is a cross-sectional view of an OLED device formed with a blanket deposition layer 730, according to one embodiment. First, a barrier layer 720 is formed on the cathode 624 to prevent ozone or hydroxyl radical from penetrating into the layers 620. Then, the blanket deposition layer 730 is formed by first exposing the OLED device to a source precursor (e.g., Trimethylaluminum (TMA)) and then to O* radicals generated from ozone without disrupting the vacuum state of the process chamber in the deposition device 100, (i.e. the blanket deposition layer is formed by in-situ).

In one embodiment, the barrier layer 720 is formed by exposing the OLED device to a source precursor and then using less-reactive radials generated from plasma other than ozone as a reactant precursor. For example, TMA may be used as a source precursor that is injected by the injector 136A for adsorption on the OLED device, and then N₂O gas may be used to generate radicals by the radical reactor 136B to provide a reactant precursor. The radicals are generated by applying a voltage difference in the radical reactor 136B. The radicals replace or react with the source precursor (e.g., TMA) and form a layer of Al₂O₃ on the OLED device by RA-ALD process.

After forming the barrier layer 720, the substrate 630 is exposed to a source precursor and then a reactant precursor to form a blanket deposition layer 730. The source precursor used in this process may be the same material used for forming the barrier layer 720 or it may be a different material. In one embodiment, the thickness of barrier layer 720 is at least 1 Å to prevent diffusion of ozone into the device but not more than 100 Å so that the OLED may retain flexibility. In order to deposit the barrier layer 720 of sufficient thickness, the process of injecting the source precursor and injecting the radicals may be repeated for a number of times.

In one embodiment, TMA is used as the source precursor for forming the blanket deposition layer 730. The reactant precursor used in the process of forming the blanket deposition layer 730 is different from the reactant precursor used in the process of forming the barrier layer 720. That is, the reactant precursor used in the process of forming the blanket deposition layer 730 includes ozone or radicals generated from ozone. The radicals can be generated, for example, by using the radical reactor 136B. It is to be noted that the barrier layer 720 previously formed on the cathode 624 prevents the ozone from damaging the layers 620 during the process of depositing the blanket deposition layer 730. Two different radical reactors may be used: one for forming the barrier layer 720 and the other for forming the blanket deposition layer 730.

FIG. 7B is a cross-sectional view of a semiconductor device comprising a plurality of photoresist mandrels 722 deposited with a blanket barrier layer 738 and a conformal blanket spacer layer 734, according to one embodiment. The radicals of ozone are also advantageous in forming a blanket oxide layer on structures such as photoresist mandrels 722. Compared to using radicals generated from oxygen, radicals generated from ozone results in a blanket oxide layer having lower stress and higher density. A denser film is better in terms of enduring the harsh conditions of an anisotropic etching process and will tend to suffer less erosion on the vertical sidewalls during anisotropic etching process (also known as an “etchback process”). Also, a higher growth rate of the oxide layer formed by using O* radicals generated from ozone plasma also results in a faster process, and therefore, the higher growth rate is beneficial to a mass-production process.

The blanket barrier layer 738 may be deposited to have a height between 0.1 nm and 10 nm thick, more preferably between 1 nm and about 5 nm thick on the photoresist mandrels 722. The blanket barrier layer 738 may be deposited at a temperature below 100° C., preferably in a temperature range of room temperature to 50° C., because photoresist materials are not tolerant to high temperatures.

The blanket barrier SiO₂ layer 738 may be formed by first exposing the mandrels 722 to a source precursor and then to radicals functioning as a reactant precursor. The source precursor may be, for example, 3DMAS (Tris(DiMethylAmino)Silane: SiH[N(CH₃)₂]₃, hexamethyldisilazane (HMDS) or DiPAS ((Di-isopropylamino)silane: SiH₃(N(C₃H₇)₂)). The radicals may be generated by N₂O or N₂O mixed with NH₃ remote plasma.

After forming the blanket barrier SiO₂ layer, the conformal blanket SiO₂ spacer layer 734 is formed. The conformal blanket SiO₂ spacer layer 734 preferably has a thickness between 10 nm to 50 nm, and more preferably between 15 nm and 30 nm. The conformal blanket SiO₂ spacer layer 734 may be formed over the barrier layer 738 by exposing the source precursor and then to O* radicals generated from ozone plasma or O* radicals with hydroxyl radicals generated from ozone plasma mixed with hydrogen. While ozone, hydrogen, O* radicals, hydroxyl radicals or combinations thereof are being injected, the mandrels 722 are protected from ozone or O* radicals by the blanket barrier SiO₂ layer.

After forming the conformal blanket SiO₂ spacer layer, anisotropical etching is performed on the blanket barrier SiO₂ layers from exposed horizontal surfaces in the device to retain the blanket barrier SiO₂ layers on vertical sidewalls of the photoresist mandrels 722 to form so-called oxide spacers composed of the sidewalls 744 and 748 as shown in FIG. 7C. Then, the photoresist materials of the mandrels 722 are removed to obtain the spaces of FIG. 7D).

FIG. 8 is a plan view of a rotating deposition apparatus 800 for depositing the barrier layer 720 and the encapsulation 730 or blanket spacer layer 734, according to one embodiment. The rotating deposition apparatus 800 includes a susceptor 428 for holding substrates 420 which is formed with OLED devices or semiconductor devices. The susceptor 428 is rotated in a counter-clockwise direction to expose the substrates 420 to different radicals and gases.

The rotating deposition apparatus 800 may include injector 812 for injecting a source precursor (e.g., TMA or 3DMAS), a first radical reactor 814, and a second radical reactor 816. The first radical reactor 814 may generate radicals using gas other than ozone (e.g., N₂O) while the second radical reactor 816 may generate radicals using ozone or ozone in combination mixed with hydrogen. When forming the barrier layer 720, the second radical reactor 816 may be inactivated while the first radical reactor 814 injects radicals onto the substrate. When forming the blanket deposition layer 730, the first radical reactor 814 may be inactivated while the second radical reactor 816 injects radicals onto the substrate. The growth rate of a deposition layer using the RA-ALD process is higher when ozone plasma is used compared to using N₂O plasma. Further, the growth rate of the deposition layer using RA-ALD process is higher when radicals are generated from the mixture of ozone and hydrogen gases compared to using ozone alone.

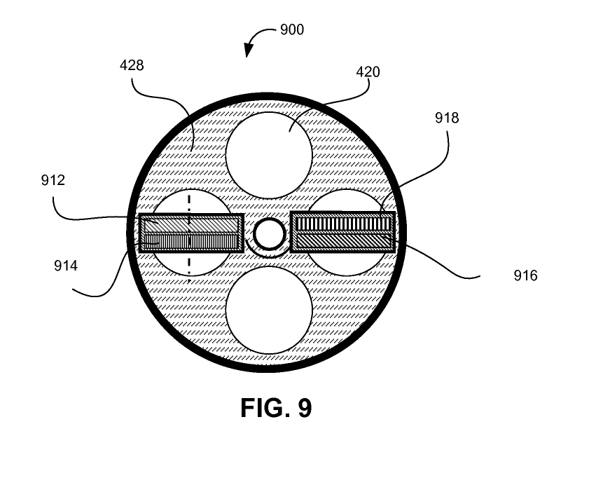

FIG. 9 is a plan view of a rotating deposition apparatus 900 for depositing a blanket deposition layer, according to another embodiment. The rotating deposition apparatus 900 has substantially the same elements as the rotating deposition apparatus 800 except that the rotating deposition apparatus 900 has an additional injector 916 to inject a source precursor different from a source precursor injected by injector 912. For example, the injector 912 injects 3DMAS that functions as a source precursor to form a SiO₂ layer as the barrier layer 720 while the injector 916 injects TMA that functions as a source precursor to form an Al₂O₃ layer as the blanket deposition layer 730. A radical reactor 914 may be provided with gas other than ozone (e.g., N₂O gas) to generate radicals that function as a reactant precursor to form the barrier layer 720. A radical reactant 918 may be provided with ozone to generate O* radicals that function as a reactant precursor to form the blanket deposition layer 730.

The arrangements of the rotating deposition apparatuses 800, 900 are merely illustrative. Various other gases may be used as source precursor and different numbers of injectors and radical reactors may be used to deposit a barrier layer and a blanket deposition layer.

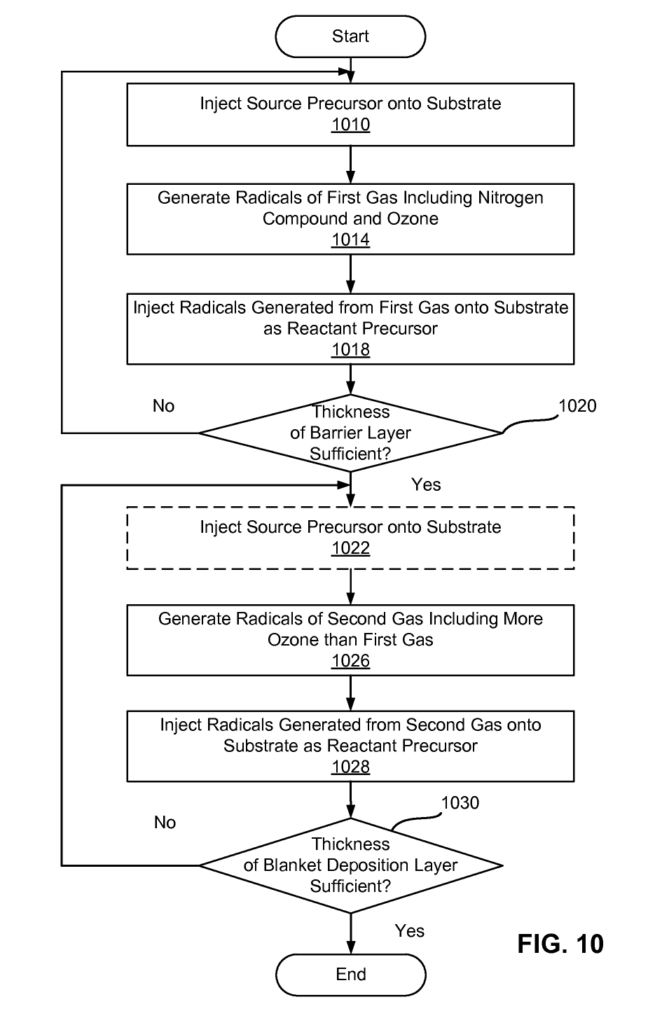

FIG. 10 is a flowchart illustrating a process of depositing a barrier layer and on a device, according to one embodiment. The composition of gas for generating the radicals may be changed while the same source precursor is retained during each repetition of RA-ALD processes to deposit the barrier layer 720 and the blanket deposition layer 730.

First, source precursor (e.g., TMA) is injected 1010 onto the substrate 630 and the layers 620. The radical reactor 136B is provided with first gas composed mostly of nitrogen compound (e.g., N₂O) and a smaller amount of ozone to generate 1014 radicals. For example, the gas may include at most 10% of ozone and at least 90% of N₂O. Alternatively, the first gas may include only nitrogen compound and no ozone. The generated radicals are injected 1018 onto the substrate as reactant precursor to form a barrier layer 720 on the substrate and the structure. It is then determined 1020 if the thickness of the barrier layer 720 is sufficient. If not, then the process returns to injecting 1010 the source precursor and repeats the subsequent steps. The RA-ALD process of injecting TMA by the injector 136A and injecting radicals of the gas composition by the radical reactor 136B may be repeated to form a barrier layer 720 of thickness 1 Å to 100 Å on the substrate 630. The RA-ALD process for depositing the barrier layer 720 does not cause damages to the layers 620 due to low content or absence of ozone. If it is determined that the thickness of the barrier layer 720 is sufficient, then the process proceeds to the process of forming a blanket deposition layer.

Then source precursor may be injected 1022 onto the substrate 630 and the layers 620 to deposit a blanket deposition layer 730. In some embodiments, the source precursor is not separately injected onto the substrate. Rather, the source precursor previously injected 1010 onto the substrate is used for depositing the blanket deposition layer 730.

Then, the radical reactor 136B is provided with second gas including more ozone compared to first gas to generate 1026 radicals. The radicals generated from the second gas is injected 1028 onto the substrate, causing the blanket deposition layer 730 to be formed on the substrate 630 by RA-ALD process. It is then determined 1030 if the blanket deposition layer 730 is of a sufficient thickness. If not, the process returns to injecting 1022 the source precursor and repeats the subsequent processes. If the thickness of the blanket deposition layer is sufficient, the process terminates.

After sufficient thickness of barrier layer 720 is formed, the portion of ozone in the gas composition is increased to deposit the blanket deposition layer 730. For example, composition gas including 10% of N₂O and 90% of ozone, or 10% to 50% of hydrogen and 50% to 90% of ozone for reactive O* radicals and hydroxyl radical generations may be used to deposit the blanket deposition layer 730 during this stage. Instead of using mixed gas of N₂O and ozone to generate radicals, mixed gas including 10% to 50% of hydrogen and ozone can be used to generate O* radicals and hydroxyl radicals for depositing the blanket deposition layer 730. The thickness of the blanket deposition layer 730 may be 100 to 1000 Å.

In one embodiment, a layer of AlN is formed as the barrier layer 720 followed by formation of a layer of Al₂O₃ as the blanket deposition layer 730. To form the barrier layer 720 and the blanket deposition layer 730, the injector 136A injects TMA as source precursor onto the OLED device. Then NH₃ is provided to the radical reactor 136B to generate N* radicals. N* radicals react with or replace TMA molecules adsorbed on the OLED device to form AlN layer.

The RA-ALD process of depositing AlN may be repeated to deposit an AlN layer of 1 to 100 Å thickness. After depositing the AlN layer as the barrier layer 720, Al₂O₃ is deposited as the blanket deposition layer 730 on the AlN layer by injecting TMA as the source precursor and radicals of ozone or radicals of ozone and hydroxyl as the radical precursor. The thickness of the deposited Al₂O₃ layer may be 100 to 1000 Å.

In one embodiment, a layer of SiO₂ is deposited as the barrier layer 720 followed by formation of a layer of Al₂O₃ as the blanket deposition layer 730. To form the barrier layer 720, Tris[dimethylamino]Silane (3DMAS) vapor is injected by the injector 136A on the substrate 630 and the cathode 624 as a source precursor. Hexamethyldisilazane (HMDS) or DiPAS may be used as a source precursor instead of 3DMAS.

Then N₂O is provided to the radical reactor 136B to generate O* radicals. O* radicals functions as a reactant precursor that reacts with or replaces 3DMAS molecules adsorbed on the OLED device to form a SiO₂ layer. The RA-ALD process may be repeated to deposit a SiO₂ layer of 1 to 100 Å thickness.

After depositing the SiO₂ layer as the barrier layer 720, Al₂O₃ is deposited as the blanket deposition layer 730 on the SiO₂ layer by injecting TMA as the source precursor and O* radicals as the radical precursor. The thickness of the deposited Al₂O₃ layer may be 100 to 1000 Å. Alternatively, the blanket deposition layer 730 may include SiO₂ formed by using O* radicals derived from ozone as the reactant precursor.

In one embodiment, a layer of Al₂O₃ is deposited as the barrier layer 720 followed by formation of a layer of TiO₂ as an optical function layer to control the transmittance of the incident light at a given wavelength. To form the barrier layer 720, TMA vapor is injected as a source precursor. After depositing the Al₂O₃ layer as the barrier layer 720, TiO₂ is deposited as the optical function layer having a refractive index larger than 2.0 at the visible wavelength on the Al₂O₃ layer by injecting Tetrakis[dimethylamino]-titanium (TDMAT) as the source precursor and the O* radicals and reactive species from ozone plasma as the reactant precursor. The thickness of the Al₂O₃ barrier layer 720 may be 1 to 100 Å, and the TiO₂ optical function layer 730 may be 100 to 1000 Å.

In one embodiment, the composition of gas for generating radicals as the reactant precursor is gradually changed. For example, the composition of gas injected into radical reactor 136B may change gradually from N₂O to O₃. In other embodiments, the composition of gas may change abruptly from one type of gas (e.g., N₂O) for depositing a barrier layer to another type of gas (e.g., O₃) for depositing a blanket deposition layer.

Although above examples are described primarily with reference to ozone and its radicals, the same principle can also be applied to hydroxyl radicals that are also very reactive and can damage structures during the process of RA-ALD process.

By providing a barrier layer on an a structure or device sensitive to environment before exposing the structure or the device to ozone and radicals generated from ozone, damage to the structure or the device by penetration of ozone into the structure or the device can be prevented during the process of depositing a blanket layer using the ozone or O* radicals generated from the ozone. Therefore, the integrity of the structure or the device is maintained during a fabrication process while providing the blanket layer of a superior quality to protect the structure or the device from moisture or oxygen after the structure or the device is fabricated.

Thus, while particular embodiments and applications have been illustrated and described, it is to be understood that the disclosed embodiments are not limited to the precise construction and components disclosed herein. Various modifications, changes and variations, may be made in the arrangement, operation and details of the method and apparatus disclosed herein without departing from the spirit and scope defined in the appended claims.

1. A method of blanket depositing a structure on a substrate, comprising:
(a) injecting source precursor onto the structure and the substrate;
(b) generating first radicals from first gas containing nitrogen compound;
(c) injecting the first radicals onto the device and the substrate to form a barrier layer by a radical assisted atomic layer deposition (RA-ALD) process;
(d) generating second radicals from second gas containing more ozone than the first gas; and
(e) injecting the second radicals onto the structure and the substrate to form a blanket deposition layer over the barrier layer by a radical assisted atomic layer deposition (RA-ALD) process.

2. The method of claim 1, further comprising repeating (a) through (c) for a predetermined number of times, and repeating (d) and (e) for a predetermined number of times.

3. The method of claim 1, further comprising injecting the source precursor onto the structure and the substrate after injecting the first radicals and before injecting the second radicals.

4. The method of claim 1, wherein the structure comprises organic light-emitting diode (OLED).

5. The method of claim 1, wherein the nitrogen compound comprises nitrous oxide.

6. The method of claim 1, wherein the nitrogen compound comprises at least one of N₂O and NH₃.

7. The method of claim 6, wherein the source precursor comprises at least one of trimethylaluminum (TMA), tris[dimethylamino]Silane (3DMAS), hexamethyldisilazane (HMDS), Di-siopropylaminosilane (DiPAS), Tetrakisdimethylaminotitanium (TDMAT), Tetrakisdimethylaminohafnium (TDMAH), and Tetrakisdimethylaminozirconium (TDMAZ).

8. The method of claim 7, wherein the barrier layer comprises at least one of AlN, SiN and SiO₂.

9. The method of claim 8, wherein the barrier layer has a thickness of 1 to 100 Å.

10. The method of claim 8, wherein the blanket deposition layer comprises at least one of Al₂O₃SiO₂, ZrO₂ and HfO₂.

11. The method of claim 10, wherein the blanket deposition layer has a thickness of 100 to 1000 Å.

12. The method of claim 1, wherein the first and second radicals are generated by remote-plasma generation.

13. The method of claim 1, wherein the second gas contains more ozone and hydrogen than the first gas.

14. The method of claim 1, wherein the pattern comprises an array of elongated photoresist mandrels.

15. A device comprising:
a substrate;
a first electrode formed on the substrate;
a second electrode;
an organic material sandwiched between the first electrode and the second electrode;
a barrier layer formed on the second electrode and the substrate by exposure to a first source precursor and first radicals generated from first gas containing nitrogen compound; and
a blanket deposition layer formed on the barrier layer by exposure to a second source precursor and second radicals generated from second gas containing more ozone than the first gas.

16. The device of claim 15, wherein the first and second source precursors are same.

17. The device of claim 15, wherein the nitrogen compound comprises nitrogen oxide.

18. The device of claim 15, wherein the nitrogen compound comprises at least one of N₂O and NH₃.

19. The device of claim 18, wherein the first source precursor comprises at least one of trimethylaluminum (TMA), tris[dimethylamino]Silane (3DMAS) and hexamethyldisilazane (HMDS), Di-siopropylaminosilane (DiPAS), Tetrakisdimethylaminotitanium (TDMAT), Tetrakisdimethylaminohafnium (TDMAH), and Tetrakisdimethylaminozirconium (TDMAZ).

20. The device of claim 18, wherein the barrier layer comprises at least one of AlN, SiN, and SiO₂.

21. The device of claim 15, wherein the barrier layer has a thickness of 1 to 100 Å and the blanket deposition layer has a thickness of 100 to 1000 Å.

22. The device of claim 15, wherein the first and second radicals are generated by remote-plasma generation.

23. A method for fabricating a semiconductor device, the method comprising:
forming a plurality of photoresist mandrels on a substrate;
using first radicals from first gas to perform a radical assisted atomic layer deposition (RA-ALD) process to blanket deposit a barrier layer on the plurality of mandrels and the substrate, the first gas containing nitrogen compound; and
using second radicals from second gas to perform a radical assisted atomic layer deposition (RA-ALD) process to form a blanket deposition layer on the barrier layer, the second gas containing more ozone than the first gas.

24. The method of claim 23, further comprising:
anisotropically etching the barrier layer and the blanket deposition layer to form spacers on sidewalls of the photoresist mandrels; and
removing the photoresist mandrels to form a plurality of spacers on the substrate.
